(19) United States
(12) Patent Application Publication
(10) Pub. No.: US 2026/0157231 A1
(43) Pub. Date: Jun. 4, 2026

(54) SEMICONDUCTOR PACKAGE

(71) Applicant: Samsung Electronics Co., Ltd., Suwon-si (KR)

(72) Inventors: Jinwoo Park, Suwon-si (KR); Seon Ho Lee, Suwon-si (KR)

(21) Appl. No.: 19/292,139

(22) Filed: Aug. 6, 2025

(30) Foreign Application Priority Data
Dec. 3, 2024 (KR) 10-2024-0177826

(51) Int. Cl. H01L 25/10; H01L 23/00; H01L 23/31; H01L 25/04

(52) U.S. Cl. CPC H10W 90/00; H10W 74/111; H10W 90/24; H10W 90/722; H10W 90/724

(57) ABSTRACT

A semiconductor package includes a first semiconductor chip, a first molding layer surrounding the first semiconductor chip, a first post structure in the first molding layer, a second semiconductor chip, a second molding layer surrounding the second semiconductor chip, a second post structure in the second molding layer, a connection structure between the first molding layer and the second molding layer, and a conductive structure surrounded by the connection structure, and disposed between the first post structure and the second post structure. The first post structure, the second post structure, and the conductive structure overlap the first semiconductor chip.

### CROSS-REFERENCE TO RELATED APPLICATION(S)

This U.S. non-provisional patent application claims priority to Korean Patent Application No. 10-2024-0177826, filed in the Korean Intellectual Property Office on Dec. 3, 2024, the disclosure of which is hereby incorporated by reference in its entirety.

### BACKGROUND

A semiconductor package is made by realizing an integrated circuit chip in a form suitable for use in an electronic product. In general, the semiconductor package is made by mounting a semiconductor chip on a printed circuit board and electrically connecting them by using a bonding wire or a bump. With development of the electronics industry, various research for improving reliability of the semiconductor package is being carried out.

### SUMMARY

In general, the present disclosure is directed toward a semiconductor package with improved electrical characteristics and reliability and a method for manufacturing the same.

According to some implementations, the present disclosure is directed to a semiconductor package that includes a first semiconductor chip, a first molding layer surrounding the first semiconductor chip, a first post structure in the first molding layer, a second semiconductor chip, a second molding layer surrounding the second semiconductor chip, a second post structure in the second molding layer, a connection structure between the first molding layer and the second molding layer, and a conductive structure surrounded by the connection structure, and disposed between the first post structure and the second post structure, wherein the first post structure, the second post structure and the conductive structure overlap the first semiconductor chip.

According to some implementations, the present disclosure is directed to a semiconductor package that includes a first semiconductor chip, a first molding layer surrounding the first semiconductor chip, a first post structure in the first molding layer, a second semiconductor chip, a second molding layer surrounding the second semiconductor chip, a second post structure in the second molding layer, a connection structure between the first molding layer and the second molding layer, and a conductive structure surrounded by the connection structure, and disposed between the first post structure and the second post structure, wherein the first post structure, the second post structure and the conductive structure are electrically connected to the first semiconductor chip.

According to some implementations, the present disclosure is directed to a semiconductor package that includes a first semiconductor chip including a first pad, a first adhesive layer in contact with an upper surface of the first semiconductor chip, a first molding layer surrounding the first semiconductor chip and the first adhesive layer, a first post structure surrounded by the first molding layer, and in contact with the first pad, a second semiconductor chip including a second pad, a second adhesive layer in contact with an upper surface of the second semiconductor chip, a second molding layer surrounding the second semiconductor chip and the second adhesive layer, a second post structure surrounded by the second molding layer, and overlapping the first post structure, a third post structure surrounded by the second molding layer, and in contact with the second pad, a connection structure between the first molding layer and the second molding layer, and a conductive structure surrounded by the connection structure, and disposed between the first post structure and the second post structure, wherein the first post structure includes a first post seed layer in contact with the first pad, and a first post in contact with the conductive structure, the second post structure includes a second post seed layer in contact with the conductive structure, and a second post in contact with the second post seed layer, and the third post structure includes a third post seed layer in contact with the second pad, and a third post in contact with the third post seed layer.

### BRIEF DESCRIPTION OF THE DRAWINGS

Example implementations will be more clearly understood from the following detailed description, taken in conjunction with the accompanying drawings.

FIG. 1A is a cross-sectional view of an example of a semiconductor package according to some implementations.

FIG. 1B is an enlarged diagram of an example of region Q1 of FIG. 1A according to some implementations.

FIGS. 2 to 22 are diagrams for describing an example of a method for manufacturing a semiconductor package according to some implementations.

FIG. 23 is a diagram for describing an example of a method for manufacturing a semiconductor package according to some implementations.

FIG. 24 is an enlarged diagram of an example of a semiconductor package according to some implementations.

FIGS. 25, 26, 27, and 28 are diagrams for describing an example of a method for manufacturing a semiconductor package according to some implementations.

FIG. 29 is a cross-sectional view of an example of a semiconductor package according to some implementations.

FIG. 30 is a diagram for describing an example of a method for manufacturing a semiconductor package according to some implementations.

FIG. 31 is a cross-sectional view of an example of a semiconductor package according to some implementations.

FIG. 32 is a diagram for describing an example of a method for manufacturing a semiconductor package according to some implementations.

FIG. 33 is a cross-sectional view of an example of a semiconductor package according to some implementations.

FIG. 34 is a diagram for describing an example of a method for manufacturing a semiconductor package according to some implementations.

### DETAILED DESCRIPTION

Hereinafter, example implementations will be explained in detail with reference to the accompanying drawings.

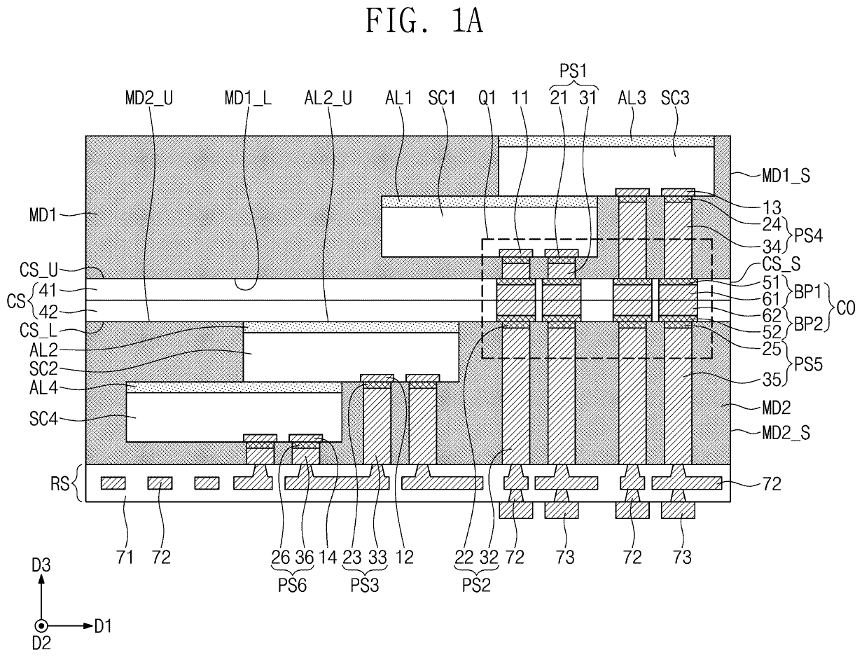

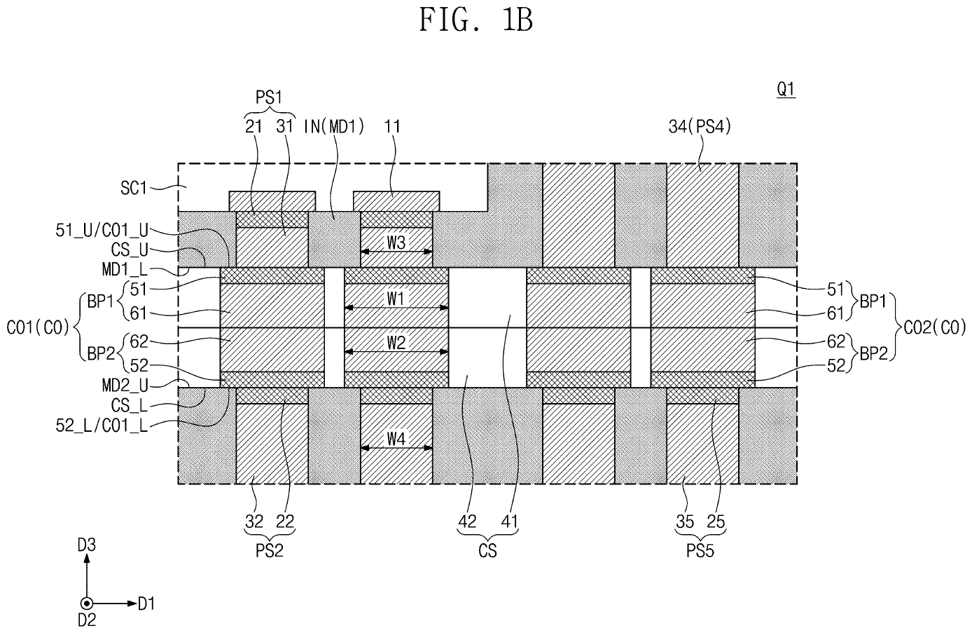

FIG. 1A is a cross-sectional view of an example of semiconductor package according to some implementations, and FIG. 1B is an enlarged diagram of an example of region Q1 of FIG. 1A according to some implementations. In FIG. 1A, a semiconductor package may include a first semiconductor chip SC1, a second semiconductor chip SC2, a third semiconductor chip SC3, a fourth semiconductor chip SC4, a first adhesive layer AL1, a second adhesive layer AL2, a third adhesive layer AL3, a fourth adhesive layer AL4, a first molding layer MD1, a second molding layer MD2, first post structures PS1, second post structures PS2, third post structures PS3, fourth post structures PS4, fifth post structures PS5, sixth post structures PS6, a connection structure CS, conductive structures CO, a redistribution structure RS, and terminals 73.

In some implementations, each of the first to fourth semiconductor chips SC1 to SC4 may include at least one of a memory element, a logic element or an image sensor element. Each of the first to fourth semiconductor chips SC1 to SC4 may include a semiconductor substrate, an insulating substrate or a semiconductor-on-insulator (SOI) substrate. For example, the semiconductor substrate may be a silicon substrate, a germanium substrate or a silicon-germanium substrate.

The first semiconductor chip SC1 may include first pads 11. The second semiconductor chip SC2 may include second pads 12. The third semiconductor chip SC3 may include third pads 13. The fourth semiconductor chip SC4 may include fourth pads 14. The first to fourth pads 11 to 14 may include a conductive material.

An upper surface and a lower surface of each of the first to fourth semiconductor chips SC1 to SC4 may be parallel to a first direction D1 and a second direction D2. The first direction D1 and the second direction D2 may cross each other. For example, the first direction D1 and the second direction D2 may be horizontal directions perpendicular to each other.

The first adhesive layer AL1 may be in contact with the upper surface of the first semiconductor chip SC1. The second adhesive layer AL2 may be in contact with the upper surface of the second semiconductor chip SC2. The third adhesive layer AL3 may be in contact with the upper surface of the third semiconductor chip SC3. The fourth adhesive layer AL4 may be in contact with the upper surface of the fourth semiconductor chip SC4. The first to fourth adhesive layers AL1 to AL4 may include a polymer material. For example, the first to fourth adhesive layers AL1 to AL4 may be a die attach film (DAF).

The first adhesive layer AL1 may be disposed between the first semiconductor chip SC1 and the third semiconductor chip SC3. The first adhesive layer AL1 may be in contact with the lower surface of the third semiconductor chip SC3. The second adhesive layer AL2 may be in contact with a lower surface CS_L of the connection structure CS. The second adhesive layer AL2 may be disposed between the connection structure CS and the second semiconductor chip SC2. The fourth adhesive layer AL4 may be disposed between the second semiconductor chip SC2 and the fourth semiconductor chip SC4. The fourth adhesive layer AL4 may be in contact with the lower surface of the second semiconductor chip SC2.

The first post structures PS1 may be provided on the conductive structure CO. The first post structure PS1 may include a first post seed layer 21 and a first post 31. The second post structures PS2 may be provided on the redistribution structure RS. The second post structure PS2 may include a second post seed layer 22 and a second post 32. The third post structures PS3 may be provided on the redistribution structure RS. The third post structure PS3 may include a third post seed layer 23 and a third post 33. The fourth post structures PS4 may be provided on the conductive structure CO. The fourth post structure PS4 may include a fourth post seed layer 24 and a fourth post 34. The fifth post structures PS5 may be provided on the redistribution structure RS. The fifth post structure PS5 may include a fifth post seed layer 25 and a fifth post 35. The sixth post structures PS6 may be provided on the redistribution structure RS. The sixth post structure PS6 may include a sixth post seed layer 26 and a sixth post 36.

The first post seed layer 21 may be in contact with the first pad 11. The first post 31 may be in contact with the first post seed layer 21 and the conductive structure CO. The second post seed layer 22 may be in contact with the conductive structure CO. The second post 32 may be in contact with the second post seed layer 22. The third post seed layer 23 may be in contact with the second pad 12. The third post 33 may be in contact with the third post seed layer 23.

The first post structure PS1 may be in contact with the first pad 11 and the conductive structure CO. The second post structure PS2 may be in contact with the conductive structure CO. The third post structure PS3 may be in contact with the second pad 12. The fourth post structure PS4 may be in contact with the conductive structure CO and the third pad 13. The fifth post structure PS5 may be in contact with the conductive structure CO. The sixth post structure PS6 may be in contact with the fourth pad 14.

The first to sixth post seed layers 21 to 26 may include a conductive material. For example, the first to sixth post seed layers 21 to 26 may include at least one of Cu, Au or Ni. According to some implementations, each of the first to sixth post seed layers 21 to 26 may be a multiple layer including a plurality of layers. For example, each of the first to sixth post seed layers 21 to 26 may include a Cu layer, a Au layer or a Ni layer.

The first to sixth posts 31 to 36 may include a conductive material. For example, the first to sixth posts 31 to 36 may include copper. According to some implementations, the first to sixth posts 31 to 36 may include different materials from the first to sixth post seed layers 21 to 26. For example, the first to sixth posts 31 to 36 may include copper, and the first to sixth post seed layers 21 to 26 may include gold, not copper.

The first molding layer MD1 may surround the first and third semiconductor chips SC1 and SC3, the first and third adhesive layers AL1 and AL3, and the first and fourth post structures PS1 and PS4. The first and third semiconductor chips SC1 and SC3, the first and third adhesive layers AL1 and AL3, and the first and fourth post structures PS1 and PS4 may be disposed in the first molding layer MD1.

The second molding layer MD2 may surround the second and fourth semiconductor chips SC2 and SC4, the second and fourth adhesive layers AL2 and AL4, and the second, third, fifth, and sixth post structures PS2, PS3, PS5, and PS6. The second and fourth semiconductor chips SC2 and SC4, the second and fourth adhesive layers AL2 and AL4, and the second, third, fifth, and sixth post structures PS2, PS3, PS5, and PS6 may be disposed in the second molding layer MD2. The second and fifth post structures PS2 and PS5 may penetrate the second molding layer MD2 in a third direction D3. The third direction D3 may cross the first direction D1 and the second direction D2. For example, the third direction D3 may be a vertical direction perpendicular to the first direction D1 and the second direction D2.

A lower surface MD1_L of the first molding layer MD1 may be in contact with an upper surface CS_U of the connection structure CS. An upper surface MD2_U of the second molding layer MD2 may be in contact with a lower surface CS_L of the connection structure CS. An upper surface AL2_U of the second adhesive layer AL2 may be in contact with the lower surface CS_L of the connection structure CS. The upper surface AL2_U of the second adhesive layer AL2 may be coplanar with the upper surface MD2_U of the second molding layer MD2.

The first and second molding layers MD1 and MD2 may include a polymer material. For example, the first and second molding layers MD1 and MD2 may include an epoxy molding compound (EMC).

The connection structure CS may be provided between first molding layer MD1 and the second molding layer MD2. A sidewall CS_S of the connection structure CS, a sidewall MD1_S of the first molding layer MD1 and a sidewall MD2_S of the second molding layer MD2 may be coplanar with each other. The sidewall CS_S of the connection structure CS, the sidewall MD1_S of the first molding layer MD1 and the sidewall MD2_S of the second molding layer MD2 may overlap each other in the third direction D3.

The connection structure CS may include a first bonding insulating layer 41 and a second bonding insulating layer 42. The first bonding insulating layer 41 and the second bonding insulating layer 42 may include different materials from the first molding layer MD1 and the second molding layer MD2. For example, the first bonding insulating layer 41 and the second bonding insulating layer 42 may include spin-on-dielectric (SOD). According to some implementations, the first bonding insulating layer 41 and the second bonding insulating layer 42 may have a structure integrally connected to each other without a boundary.

The first bonding insulating layer 41 may be in contact with the first molding layer MD1 and the second bonding insulating layer 42. The second bonding insulating layer 42 may be in contact with the second molding layer MD2.

The connection structure CS may surround the conductive structures CO. The conductive structures CO may be provided in the connection structure CS. The conductive structure CO may be disposed between the first and second post structures PS1 and PS2 or between the fourth and fifth post structures PS4 and PS5.

The conductive structure CO may include a first bonding pad BP1 and a second bonding pad BP2. The first bonding pad BP1 may be disposed in the first bonding insulating layer 41. The first bonding pad BP1 may be surrounded by the first bonding insulating layer 41. The second bonding pad BP2 may be disposed in the second bonding insulating layer 42. The second bonding pad BP2 may be surrounded by the second bonding insulating layer 42. The first bonding pad BP1 and the second bonding pad BP2 may be in contact with each other. The first bonding pad BP1 may be in contact with the first post structure PS1 or the fourth post structure PS4. The second bonding pad BP2 may be in contact with the second post structure PS2 or the fifth post structure PS5.

The first bonding pad BP1 may include a first bonding seed layer 51 and a first bonding conductive layer 61. The second bonding pad BP2 may include a second bonding seed layer 52 and a second bonding conductive layer 62. The first and second bonding seed layers 51 and 52 may include a conductive material. For example, the first and second bonding seed layers 51 and 52 may include at least one of Cu, Au or Ni. According to some implementations, each of the first and second bonding seed layers 51 and 52 may be a multiple layer including a plurality of layers. For example, each of the first and second bonding seed layers 51 and 52 may include a Cu layer, a Au layer or a Ni layer.

The first and second bonding conductive layers 61 and 62 may include a conductive material. For example, the first and second bonding conductive layers 61 and 62 may include copper. According to some implementations, the first and second bonding conductive layers 61 and 62 may include different materials from the first and second bonding seed layers 51 and 52. For example, the first and second bonding conductive layers 61 and 62 may include copper, and the first and second bonding seed layers 51 and 52 may include gold, not copper. According to some implementations, the first and second bonding conductive layers 61 and 62 may have a structure integrally connected to each other without a boundary.

The first pad 11, the first post structure PS1, the conductive structure CO and the second post structure PS2 of the first semiconductor chip SC1 may overlap each other in the third direction D3. The first post structure PS1, the conductive structure CO and the second post structure PS2 may be electrically connected to the first pad 11 of the first semiconductor chip SC1.

The first pad 11, the first post seed layer 21, the first post 31, the first bonding seed layer 51, the first bonding conductive layer 61, the second bonding conductive layer 62, the second bonding seed layer 52, the second post seed layer 22 and the second post 32 of the first semiconductor chip SC1 may overlap each other in the third direction D3. The first post seed layer 21, the first post 31, the first bonding seed layer 51, the first bonding conductive layer 61, the second bonding conductive layer 62, the second bonding seed layer 52, the second post seed layer 22 and the second post 32 may be electrically connected to the first pad 11 of the first semiconductor chip SC1.

The third pads 13, the fourth post structure PS4, the conductive structure CO and the fifth post structure PS5 of the third semiconductor chip SC3 may overlap each other in the third direction D3. The fourth post structure PS4, the conductive structure CO and the fifth post structure PS5 may be electrically connected to the third pad 13 of the third semiconductor chip SC3.

The first post 31, the first bonding seed layer 51, the first bonding conductive layer 61, the second bonding conductive layer 62, the second bonding seed layer 52 and the second post seed layer 22 may be disposed between the first post seed layer 21 and the second post 32. The first bonding seed layer 51, the first bonding conductive layer 61, the second bonding conductive layer 62 and the second bonding seed layer 52 may be disposed between the first post 31 and the second post seed layer 22. The first bonding conductive layer 61 and the second bonding conductive layer 62 may be disposed between the first bonding seed layer 51 and the second bonding seed layer 52.

The second pads 12 and the third post structure PS3 of the second semiconductor chip SC2 may overlap each other in the third direction D3. The third post structure PS3 may be electrically connected to the second pad 12 of the second semiconductor chip SC2.

The fourth pads 14 and the sixth post structure PS6 of the fourth semiconductor chip SC4 may overlap each other in the third direction D3. The sixth post structure PS6 may be electrically connected to the fourth pad 14 of the fourth semiconductor chip SC4.

The second molding layer MD2 may be provided on the redistribution structure RS. The redistribution structure RS may include a photosensitive insulating layer 71 and redistribution patterns 72. The photosensitive insulating layer 71 may include a photosensitive insulating material. According to some implementations, the photosensitive insulating layer 71 may be a multiple layer including a plurality of layers. The redistribution patterns 72 may include a conductive material.

The terminals 73 may be connected to the redistribution structure RS. The terminals 73 may include a conductive material. For example, the terminal 73 may be a bump.

Each of the second, third, fifth, and sixth post structures PS2, PS3, PS5, and PS6 may be in contact with the redistribution pattern 72. Each of the second, third, fifth, and sixth post structures PS2, PS3, PS5, and PS6 may be electrically connected to the redistribution pattern 72. The terminal 73 may be electrically connected to the redistribution pattern 72.

In FIG. 1B, the conductive structures CO may include a first conductive structure CO1 between the first post structure PS1 and the second post structure PS2 and a second conductive structure CO2 between the fourth post structure PS4 and the fifth post structure PS5.

The first conductive structure CO1 may be in contact with the second post seed layer 22 and the first post 31. An upper surface CO1_U of the first conductive structure CO1 may be coplanar with the upper surface CS_U of the connection structure CS. A lower surface CO1_L of the first conductive structure CO1 may be coplanar with the lower surface CS_L of the connection structure CS.

The first post seed layer 21 may be in contact with the first pad 11. The first post 31 may be in contact with the first bonding seed layer 51 of the first conductive structure CO1. The second post seed layer 22 may be in contact with the second bonding seed layer 52 of the first conductive structure CO1. The second post 32 may be spaced apart from the second bonding seed layer 52 of the first conductive structure CO1. The first post seed layer 21 may be spaced apart from the first bonding seed layer 51 of the first conductive structure CO1.

A lower surface of the first post 31 may be coplanar with the lower surface MD1_L of the first molding layer MD1. An upper surface of the second post seed layer 22 may be coplanar with the upper surface MD2_U of the second molding layer MD2.

An upper surface 51_U of the first bonding seed layer 51 of the first conductive structure CO1 may be in contact with the lower surface MD1_L of the first molding layer MD1. A lower surface 52_L of the second bonding seed layer 52 of the first conductive structure CO1 may be in contact with the upper surface MD2_U of the second molding layer MD2. The upper surface 51_U of the first bonding seed layer 51 of the first conductive structure CO1 may be the upper surface CO1_U of the first conductive structure CO1. The lower surface 52_L of the second bonding seed layer 52 of the first conductive structure CO1 may be the lower surface CO1_L of the first conductive structure CO1.

A width W1 in the first direction D1 of the first bonding pad BP1 and a width W2 in the first direction D1 of the second bonding pad BP2 may be greater than a width W3 in the first direction D1 of the first post structure PS1 and a width W4 in the first direction D1 of the second post structure PS2.

According to some implementations, the width W1 in the first direction D1 of the first bonding pad BP1 may become smaller as a level thereof increases, and the width W2 in the first direction D1 of the second bonding pad BP2 may become greater as a level thereof increases.

The first molding layer MD1 may include an interposed portion IN between the first bonding insulating layer 41 of the connection structure CS and the first semiconductor chip SC1. The interposed portion IN may surround the first post seed layer 21 and the first post 31 of the first post structure PS1.

Sidewalls of the first bonding seed layer 51 and the first bonding seed layer 51 may be in contact with the first bonding insulating layer 41. Sidewalls of the second bonding seed layer 52 and the second bonding conductive layer 62 may be in contact with the second bonding insulating layer 42.

Since the semiconductor package includes a conductive structure and post structures overlapping each other, reliability of electrical connection between a redistribution pattern and a pad of the semiconductor chip may be improved.

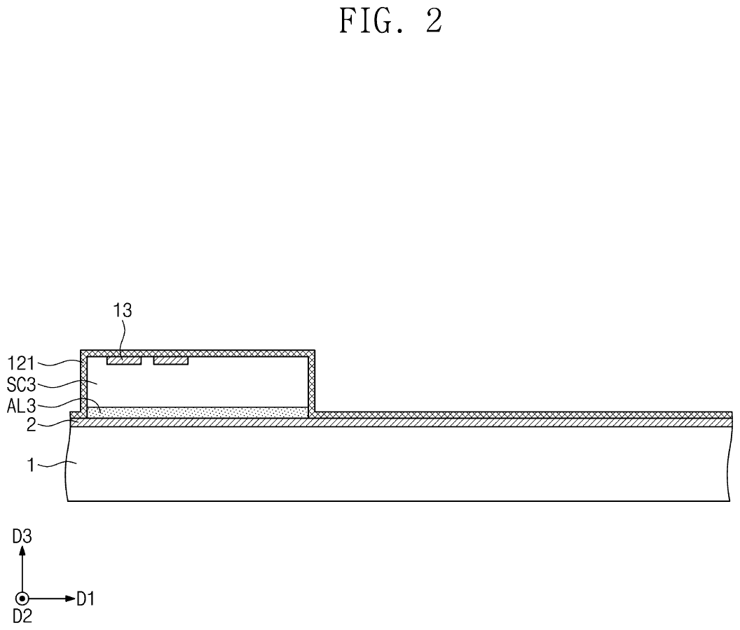

FIGS. 2 to 22 are diagrams for describing an example of a method for manufacturing a semiconductor package according to some implementations. In FIG. 2, a first sacrificial layer 2 may be formed on a first carrier substrate 1. The third adhesive layer AL3 and the third semiconductor chip SC3 may be formed on the first sacrificial layer 2. For example, the first carrier substrate 1 may be a silicon substrate or a glass substrate. For example, the first sacrificial layer 2 may include metal.

A first preliminary seed layer 121 covering the first sacrificial layer 2, the third adhesive layer AL3 and the third semiconductor chip SC3 may be formed. The first preliminary seed layer 121 may include a conductive material. For example, the first preliminary seed layer 121 may include at least one of Cu, Au or Ni.

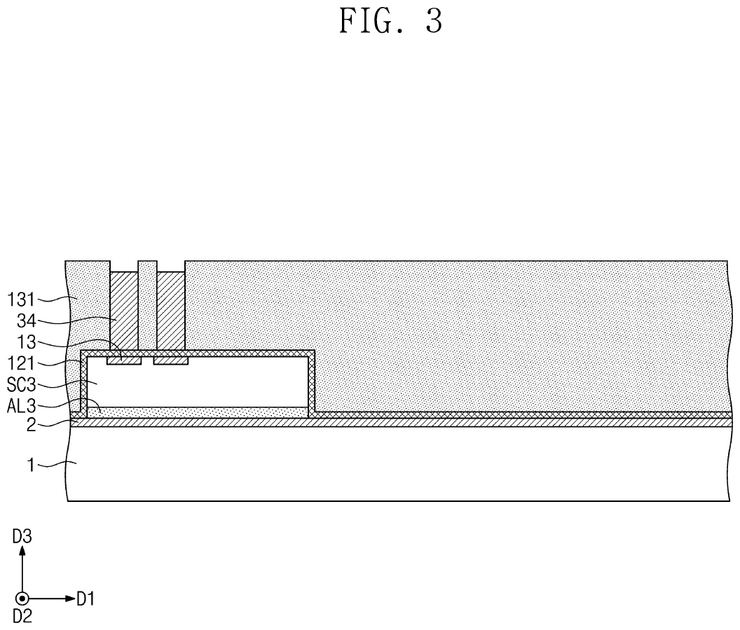

In FIG. 3, a first photoresist layer 131 may be formed on the first preliminary seed layer 121. The first photoresist layer 131 may include a photoresist material.

The fourth posts 34 may be formed. The fourth posts 34 may be formed on the first preliminary seed layer 121. According to some implementations, forming the fourth posts 34 may include forming holes exposing the first preliminary seed layer 121 by patterning the first photoresist layer 131, and forming the fourth posts 34 by using an electroplating process using the first preliminary seed layer 121 as a seed.

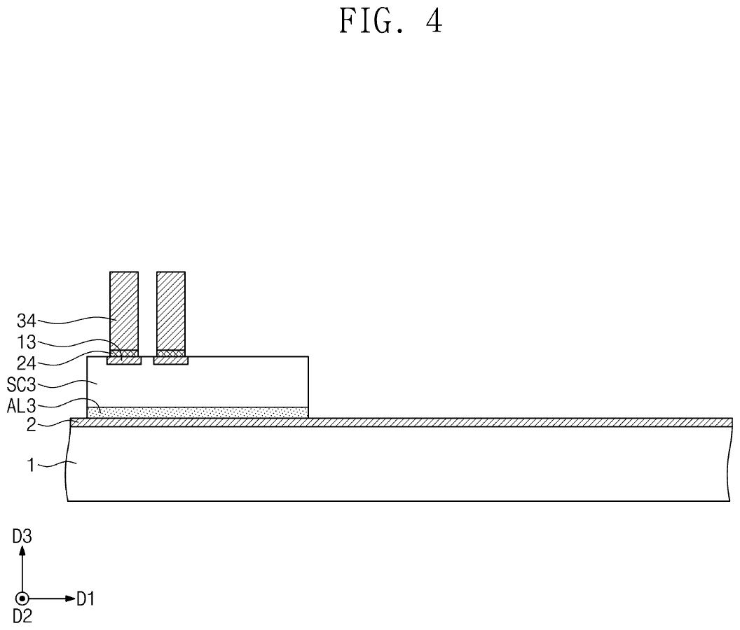

In FIG. 4, the first photoresist layer 131 may be removed. The first preliminary seed layer 121 may be etched. The fourth post seed layers 24 may be formed by etching the first preliminary seed layer 121.

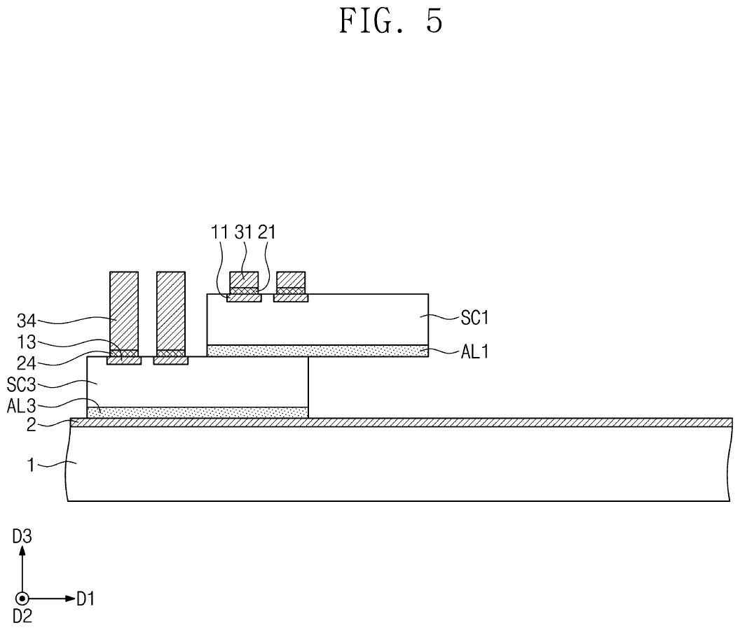

In FIG. 5, the first adhesive layer AL1 and the first semiconductor chip SC1 may be formed on the third semiconductor chip SC3. The first post seed layers 21 and the first posts 31 may be formed on the first semiconductor chip SC1. A process of forming the first post seed layers 21 and the first posts 31 may be similar to a process of forming the fourth post seed layers 24 and the fourth posts 34.

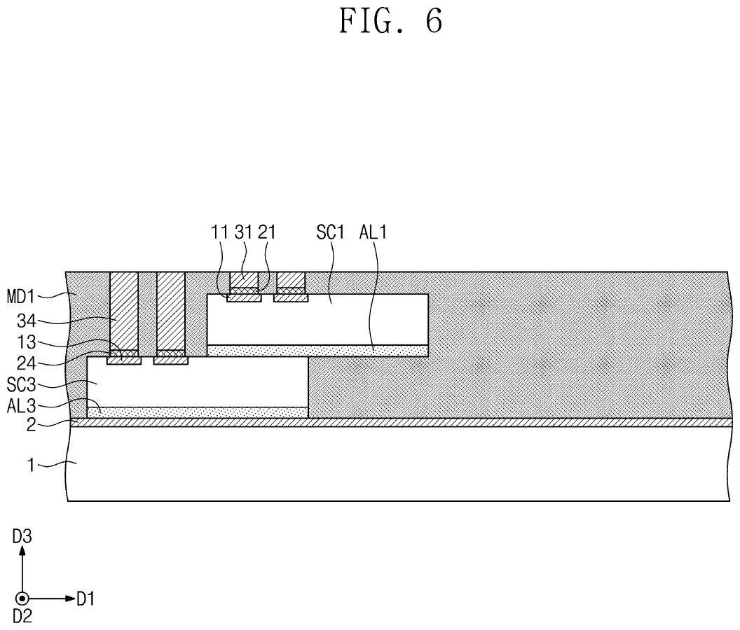

In FIG. 6, the first molding layer MD1 may be formed. According to some implementations, after the first molding layer MD1 is formed, an upper portion of the first molding layer MD1 may be removed, for example, using a grinder.

According to some implementations, a process of semi-curing the first molding layer MD1 may be performed. For example, the first molding layer MD1 may be cured by about 60% to about 80% in the semi-curing process.

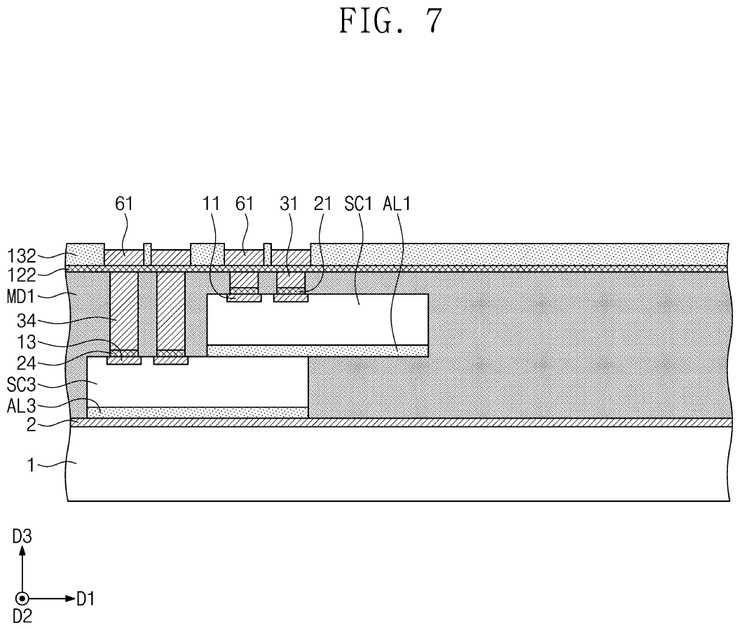

In FIG. 7, a second preliminary seed layer 122 may be formed on the first molding layer MD1, the first post 31, and the fourth posts 34. The second preliminary seed layer 122 may include a conductive material. For example, the second preliminary seed layer 122 may include at least one of Cu, Au or Ni.

A second photoresist layer 132 may be formed on the second preliminary seed layer 122. The second photoresist layer 132 may include a photoresist material.

The first bonding conductive layers 61 may be formed. The first bonding conductive layers 61 may be formed on the second preliminary seed layer 122. According to some implementations, forming the first bonding conductive layers 61 may include forming holes exposing the second preliminary seed layer 122 by patterning the second photoresist layer 132, and forming the first bonding conductive layers 61 by using an electroplating process using the second preliminary seed layer 122 as a seed.

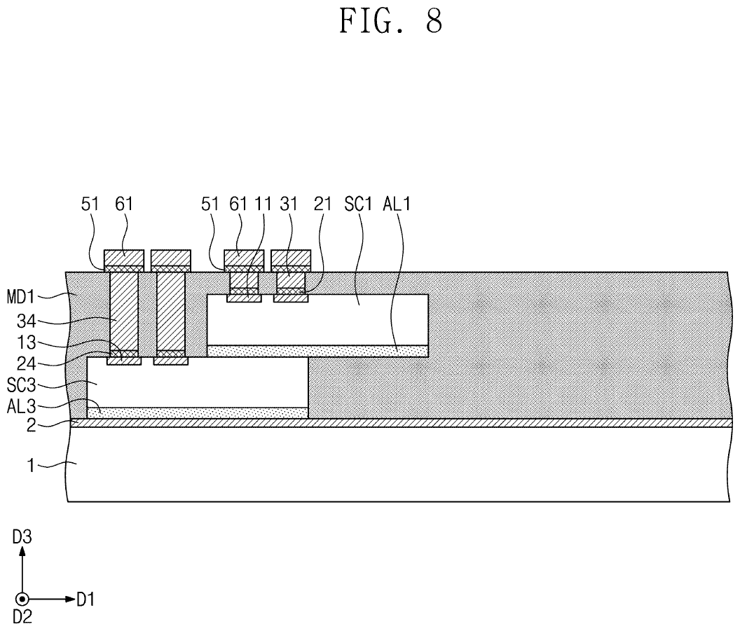

In FIG. 8, the second photoresist layer 132 may be removed. The second preliminary seed layer 122 may be etched. The first bonding seed layers 51 may be formed by etching the second preliminary seed layer 122.

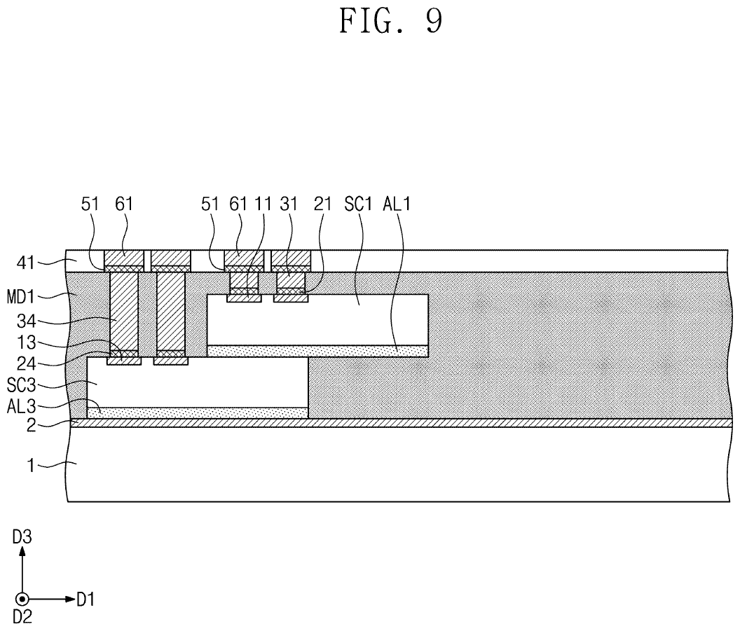

In FIG. 9, the first bonding insulating layer 41 may be formed. According to some implementations, a process of semi-curing the first bonding insulating layer 41 may be performed.

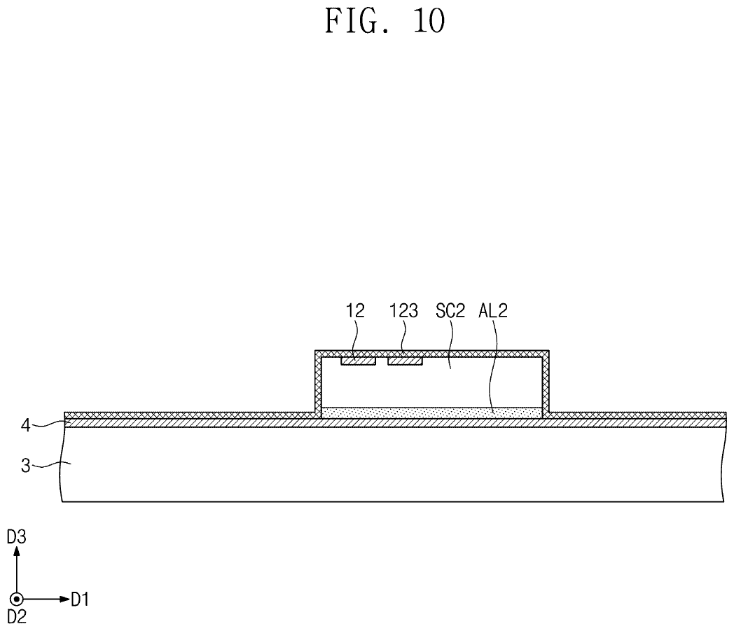

In FIG. 10, a second sacrificial layer 4 may be formed on a second carrier substrate 3. The second adhesive layer AL2 and the second semiconductor chip SC2 may be formed on the second sacrificial layer 4. For example, the second carrier substrate 3 may be a silicon substrate or a glass substrate. For example, the second sacrificial layer 4 may include metal.

A third preliminary seed layer 123 covering the second sacrificial layer 4, the second adhesive layer AL2, and the second semiconductor chip SC2 may be formed. The third preliminary seed layer 123 may include a conductive material. For example, the third preliminary seed layer 123 may include at least one of Cu, Au, or Ni.

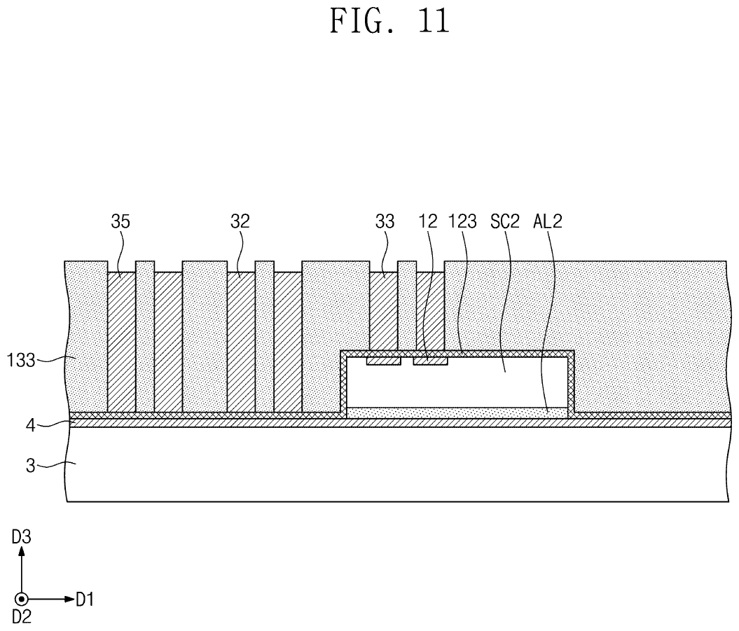

In FIG. 11, a third photoresist layer 133 may be formed on the third preliminary seed layer 123. The third photoresist layer 133 may include a photoresist material.

The second, third, and fifth posts 32, 33, and 35 may be formed. The second, third, and fifth posts 32, 33, and 35 may be formed on the third preliminary seed layer 123. According to some embodiments, forming the second, third, and fifth posts 32, 33, and 35 may include forming holes exposing the third preliminary seed layer 123 by patterning the third photoresist layer 133, and forming the second, third, and fifth posts 32, 33, and 35 by using an electroplating process using the third preliminary seed layer 123 as a seed.

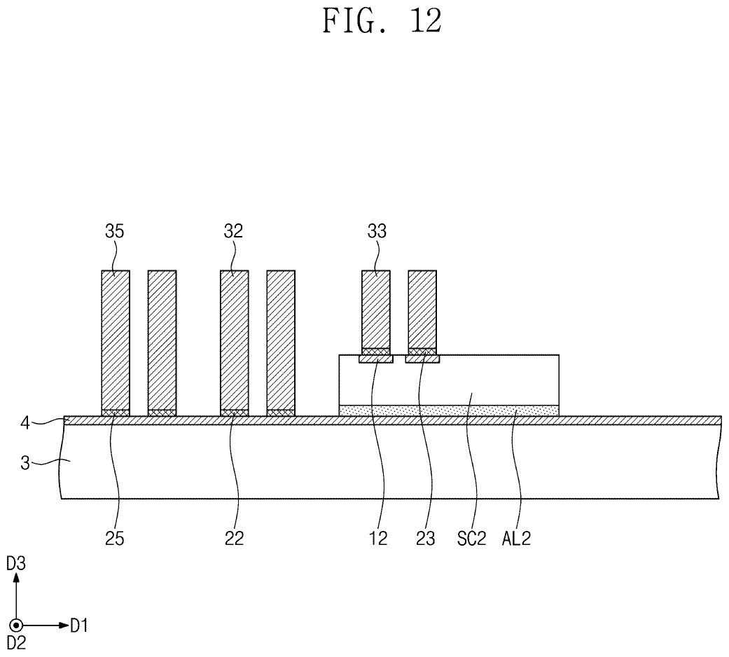

In FIG. 12, the third photoresist layer 133 may be removed. The third preliminary seed layer 123 may be etched. The second, third, and fifth post seed layers 22, 23, and 25 may be formed by etching the third preliminary seed layer 123.

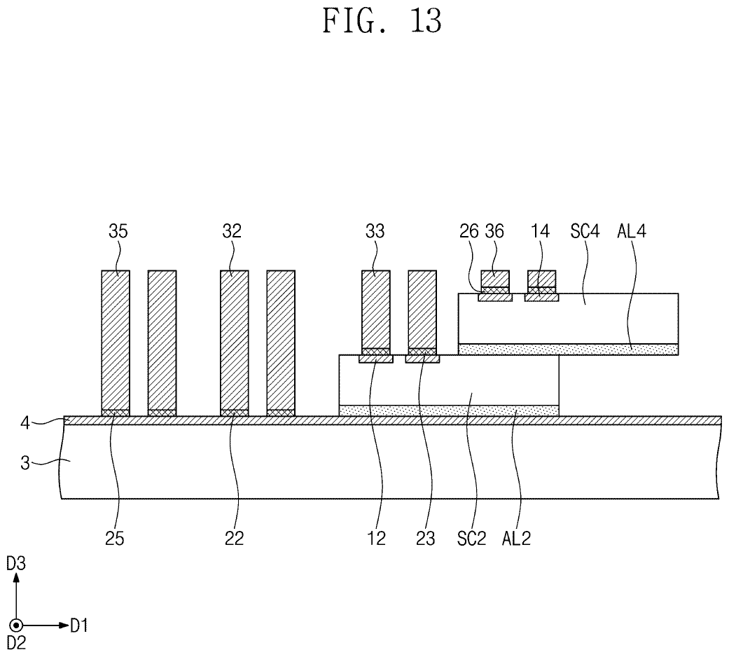

In FIG. 13, the fourth adhesive layer AL4 and the fourth semiconductor chip SC4 may be formed on the second semiconductor chip SC2. The sixth post seed layers 26 and the sixth posts 36 may be formed on the fourth semiconductor chip SC4. A process of forming the sixth post seed layers 26 and the sixth posts 36 may be similar to a process of forming the fourth post seed layers 24 and the fourth posts 34.

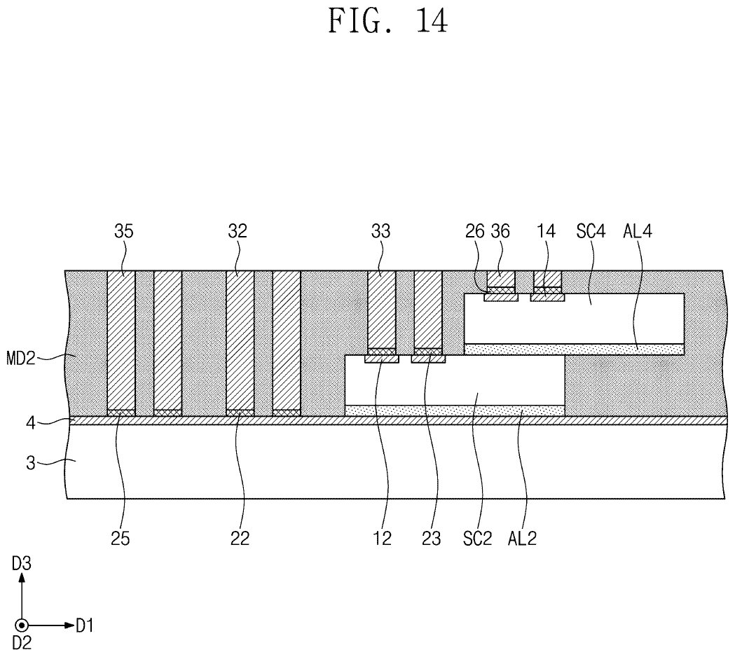

In FIG. 14, the second molding layer MD2 may be formed. According to some embodiments, after the second molding layer MD2 is formed, an upper portion of the second molding layer MD2 may be removed, for example, using a grinder.

According to some implementations, a process of semi-curing the second molding layer MD2 may be performed. For example, the second molding layer MD2 may be cured by about 60% to about 80% in the semi-curing process.

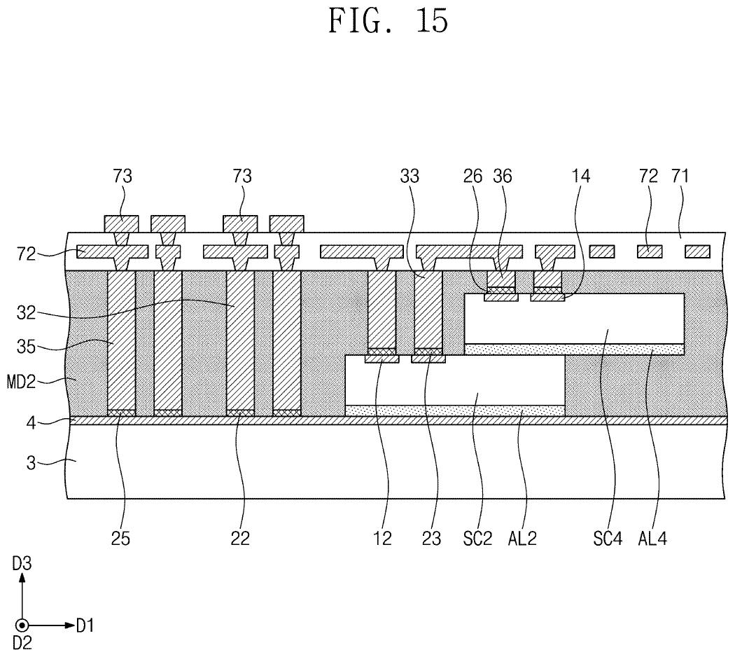

In FIG. 15, the photosensitive insulating layer 71 and the redistribution patterns 72 may be formed on the second molding layer MD2. The terminals 73 may be formed on the photosensitive insulating layer 71.

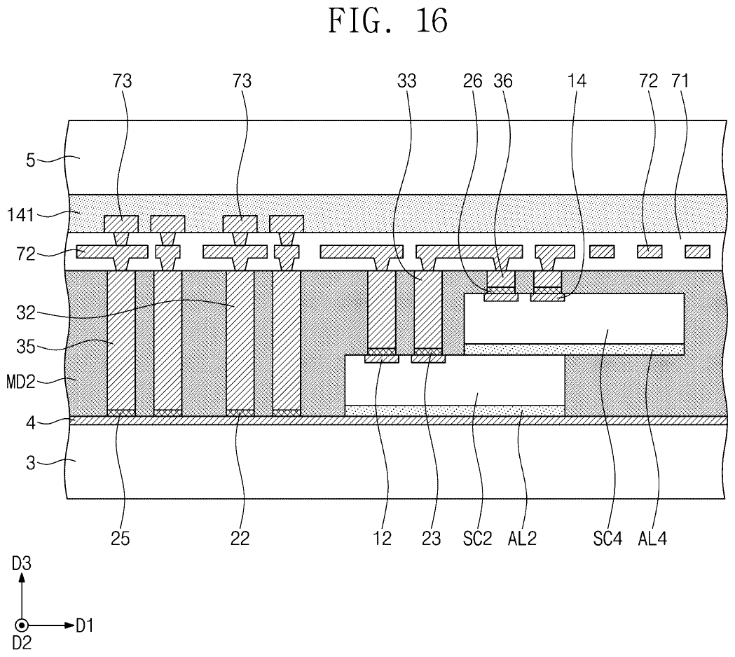

In FIG. 16, a glue layer 141 may be formed on the photosensitive insulating layer 71. The glue layer 141 may include a polymer material.

A third carrier substrate 5 may be attached onto the glue layer 141. For example, the third carrier substrate 5 may be a silicon substrate or a glass substrate.

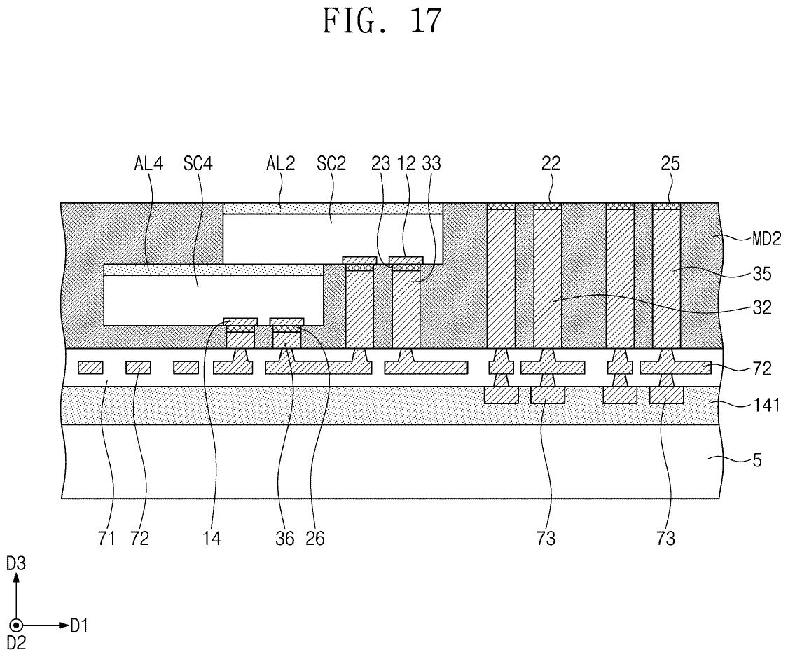

In FIG. 17, the third carrier substrate 5 may be turned over, and the second carrier substrate 3 may be separated from the second sacrificial layer 4. The second sacrificial layer 4 may be removed. For example, the second sacrificial layer 4 may be removed in an etching process. The second sacrificial layer 4 may be removed to expose the second adhesive layer AL2, the second post seed layers 22 and the fifth post seed layers 25.

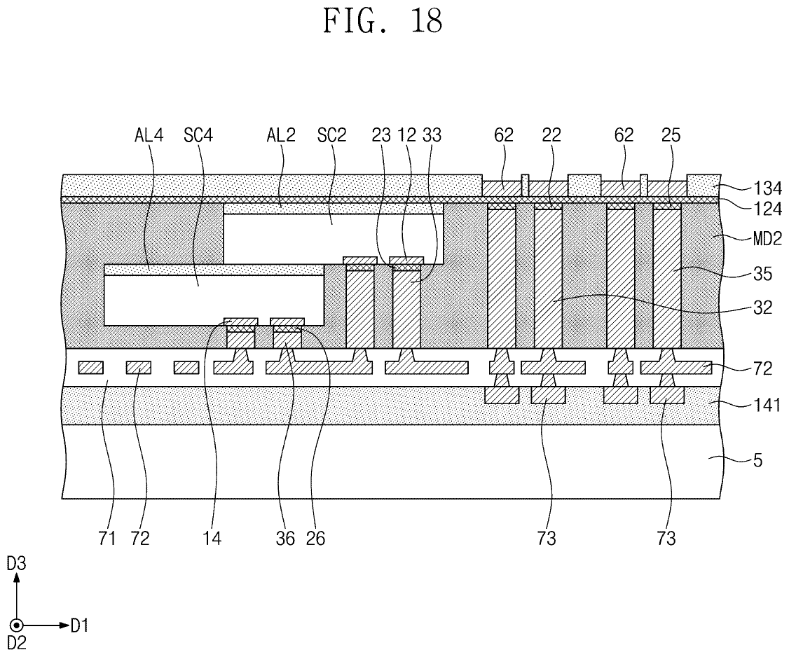

In FIG. 18, a fourth preliminary seed layer 124 may be formed on the second molding layer MD2, the second adhesive layer AL2, the second post seed layers 22, and the fifth post seed layers 25. The fourth preliminary seed layer 124 may include a conductive material. For example, the fourth preliminary seed layer 124 may include at least one of Cu, Au, or Ni.

A fourth photoresist layer 134 may be formed on the fourth preliminary seed layer 124. The fourth photoresist layer 134 may include a photoresist material.

The second bonding conductive layers 62 may be formed. The second bonding conductive layers 62 may be formed on the fourth preliminary seed layer 124. According to some implementations, forming the second bonding conductive layers 62 may include forming holes exposing the fourth preliminary seed layer 124 by patterning the fourth photoresist layer 134, and forming the second bonding conductive layers 62 by suing an electroplating process using the fourth preliminary seed layer 124 as a seed.

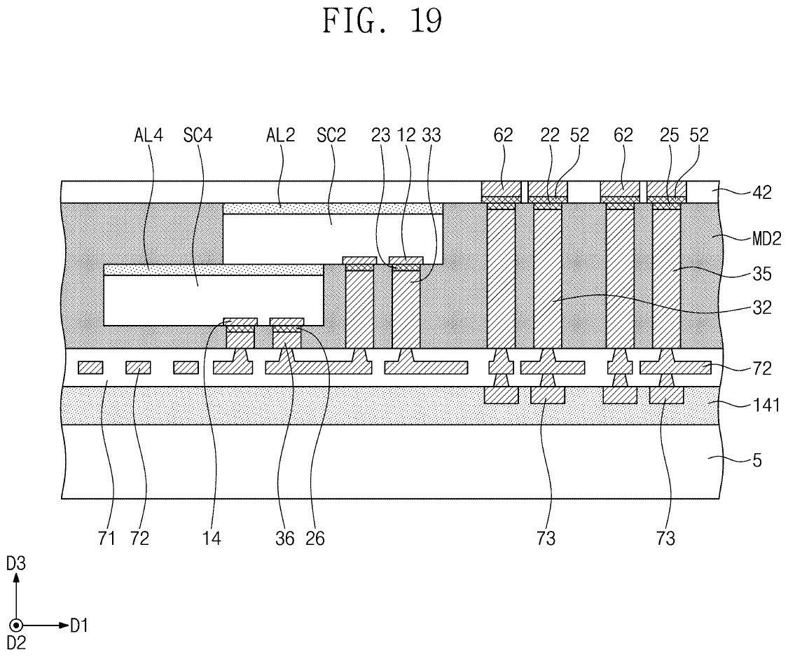

In FIG. 19, the fourth photoresist layer 134 may be removed. The fourth preliminary seed layer 124 may be etched. The second bonding seed layers 52 may be formed by etching the fourth preliminary seed layer 124. The second bonding insulating layer 42 may be formed. According to some implementations, a process of semi-curing the second bonding insulating layer 42 may be performed.

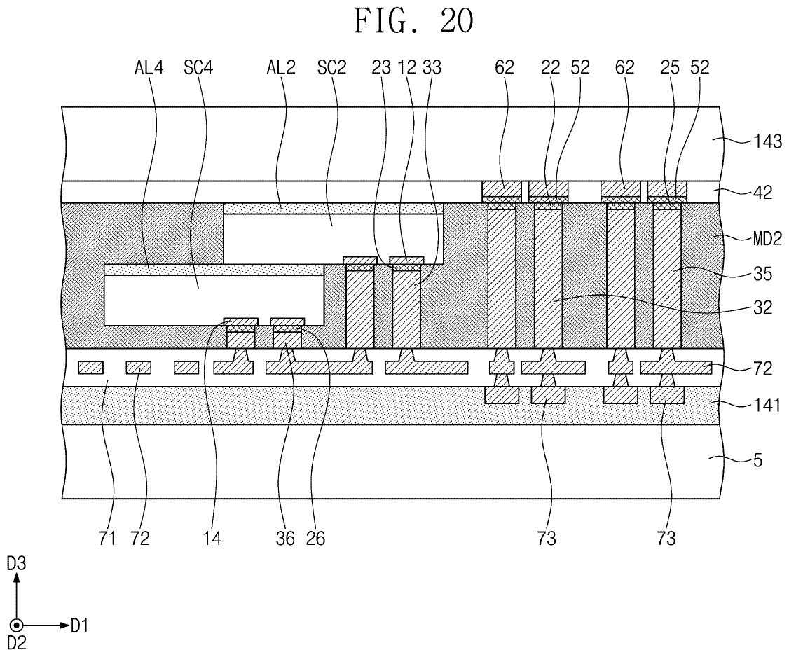

In FIG. 20, a tape 143 may be attached to the second bonding insulating layer 42. The tape 143 may include a polymer material.

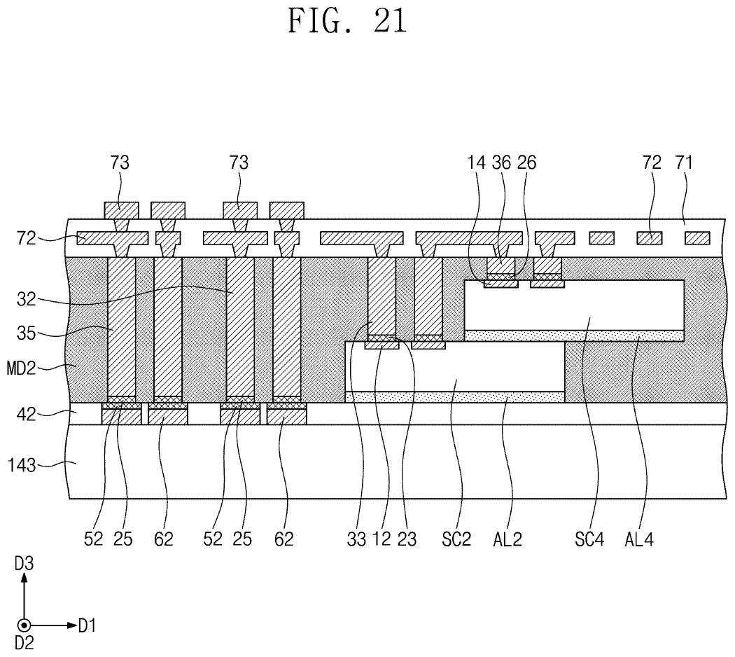

In FIG. 21, the tape 143 may be turned over. The third carrier substrate 5 and the glue layer 141 may be removed.

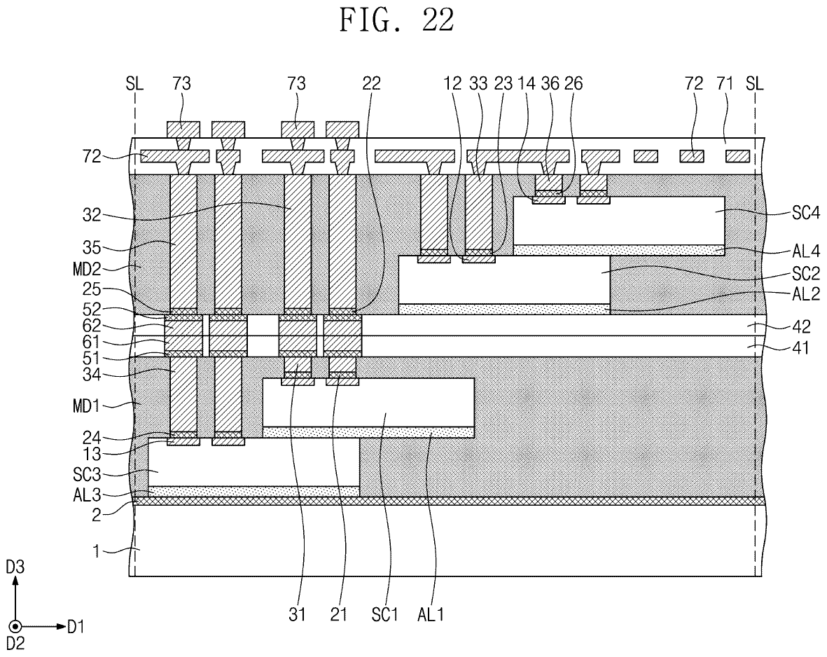

In FIG. 22, a wafer bonding process may be performed. For example, the wafer bonding process may be a hybrid Cu bonding process.

The wafer bonding process may include separating the second bonding insulating layer 42 from the tape 143, bonding the second bonding insulating layer 42 to the first bonding insulating layer 41, and bonding the second bonding conductive layer 62 to the first bonding conductive layer 61.

A curing process may be performed. For example, the curing process may include an annealing process. The first molding layer MD1, the second molding layer MD2, the first bonding insulating layer 41, and the second bonding insulating layer 42 may be completely cured in the curing process.

A scribing process may be performed along a scribe lane SL.

In FIG. 1A, the first carrier substrate 1 may be turned over.

The first carrier substrate 1 may be separated from the first sacrificial layer 2. The first sacrificial layer 2 may be removed. For example, the first sacrificial layer 2 may be removed in an etching process.

According to the method for manufacturing a semiconductor package, an upper structure and a lower structure are separately manufactured, and then may be bonded to each other through the wafer bonding process. Accordingly, stability of processes of manufacturing post structures overlapping each other may be improved.

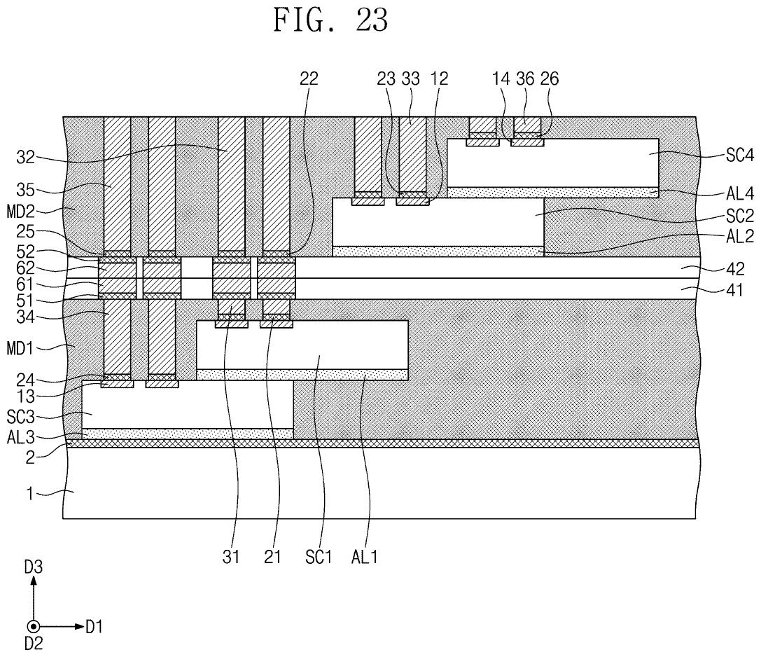

FIG. 23 is a diagram for describing an example of a method for manufacturing a semiconductor package according to some implementations. Except for what is subsequently described, the method for manufacturing a semiconductor package according to FIG. 23 may be similar to the method for manufacturing a semiconductor package according to FIGS. 2 to 22.

In FIG. 23, before the photosensitive insulating layer 71, the redistribution patterns 72, and the terminals 73 are formed on the second molding layer MD2, the second bonding insulating layer 42, the second bonding seed layers 52, and the second bonding conductive layers 62 may be formed.

The second bonding insulating layer 42 and the first bonding insulating layer 41 may be bonded to each other, and the first bonding conductive layer 61 and the second bonding conductive layer 62 may be bonded to each other.

In FIG. 1A, after the wafer bonding process is performed, the photosensitive insulating layer 71, the redistribution patterns 72, and the terminals 73 may be formed. Subsequently, the scribing process may be performed.

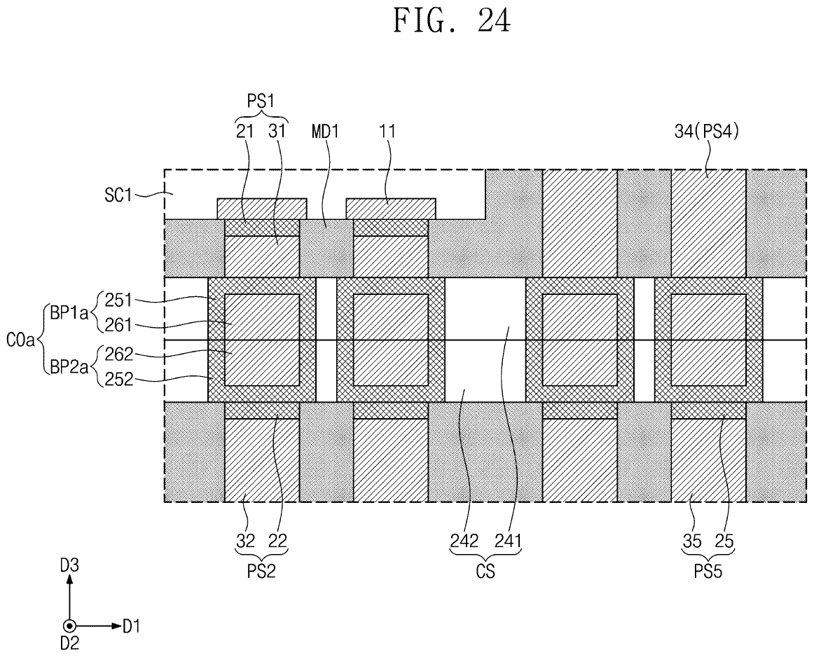

FIG. 24 is an enlarged diagram of an example of a semiconductor package according to some implementations. Except for what is described below, the semiconductor package according to FIG. 24 may be similar to the semiconductor package according to FIGS. 1A and 1B.

In FIG. 24, a conductive structure COa may include a first bonding pad BP1a and a second bonding pad BP2a. The first bonding pad BP1a may include a first bonding seed layer 251 and a first bonding conductive layer 261. The second bonding pad BP2a may include a second bonding seed layer 252 and a second bonding conductive layer 262.

The first bonding seed layer 251 may surround the first bonding conductive layer 261. The second bonding seed layer 252 may surround the second bonding conductive layer 262. The first bonding seed layer 251 may be in contact with the second bonding seed layer 252.

A connection structure CSa may include a first bonding insulating layer 241 and a second bonding insulating layer 242. The first bonding conductive layer 261 may be spaced apart from the first bonding insulating layer 241. The first bonding seed layer 251 may be partially interposed between the first bonding insulating layer 241 and the first bonding conductive layer 261. The second bonding conductive layer 262 may be spaced apart from the second bonding insulating layer 242. The second bonding seed layer 252 may be partially interposed between the second bonding insulating layer 242 and the second bonding conductive layer 262.

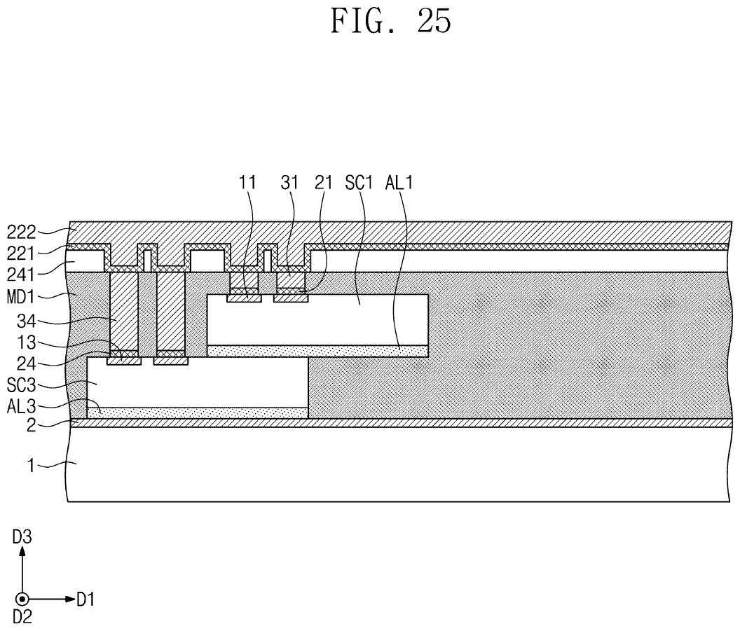

FIGS. 25 to 28 are diagrams for describing an example of a method for manufacturing a semiconductor package according to some implementations. Except for what is subsequently described, the method for manufacturing a semiconductor package according to FIGS. 25 to 28 may be similar to the method for manufacturing a semiconductor package according to FIGS. 2 to 22.

In FIG. 25, the first bonding insulating layer 241 may be formed on the first molding layer MD1, the first posts 31, and the fourth posts 34. A first preliminary seed layer 221 may be formed on the first bonding insulating layer 241. Forming the first preliminary seed layer 221 may include forming holes exposing the first and fourth posts 31 and 34 by patterning the first bonding insulating layer 241, and forming the first preliminary seed layer 221 on the exposed first and fourth posts 31 and 34.

A first preliminary conductive layer 222 may be formed on the first preliminary seed layer 221. The first preliminary conductive layer 222 may completely fill the holes of the first bonding insulating layer 241.

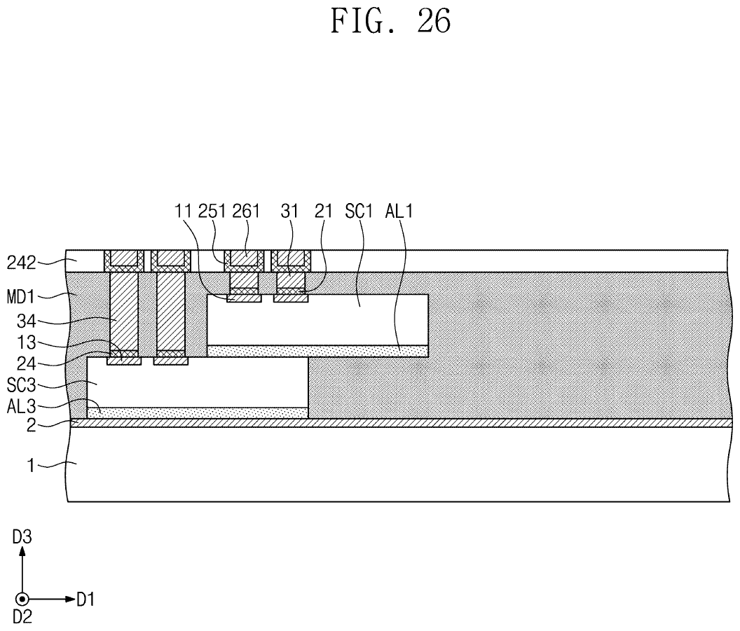

In FIG. 26, an upper portion of the first preliminary seed layer 221 and an upper portion of the first preliminary conductive layer 222 may be removed. For example, the upper portion of the first preliminary seed layer 221 and the upper portion of the first preliminary conductive layer 222 may be removed in a chemical mechanical polishing (CMP) process.

The upper portion of the first preliminary seed layer 221 may be removed to form the first bonding seed layers 251. The upper portion of the first preliminary conductive layer 222 may be removed to form the first bonding conductive layers 261.

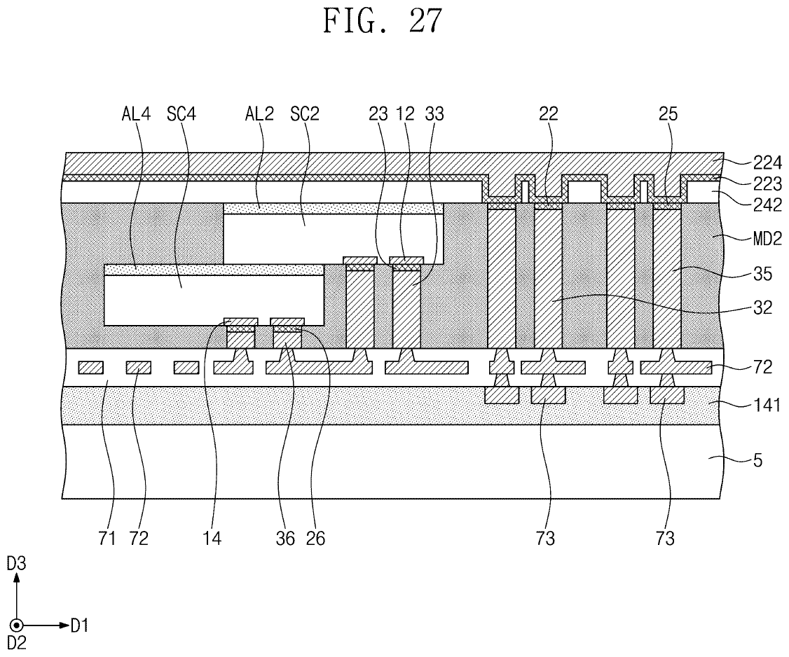

In FIG. 27, the second bonding insulating layer 242 may be formed on the second molding layer MD2, the second adhesive layer AL2, the second post seed layers 22, and the fifth post seed layers 25. A second preliminary seed layer 223 may be formed on the second bonding insulating layer 242. Forming the second preliminary seed layer 223 may include forming holes exposing the second and fifth post seed layers 22 and 25 by patterning the second bonding insulating layer 242, and forming the second preliminary seed layer 223 on the exposed second and fifth post seed layers 22 and 25.

A second preliminary conductive layer 224 may be formed on the second preliminary seed layer 223. The second preliminary conductive layer 224 may completely fill the holes of the second bonding insulating layer 242.

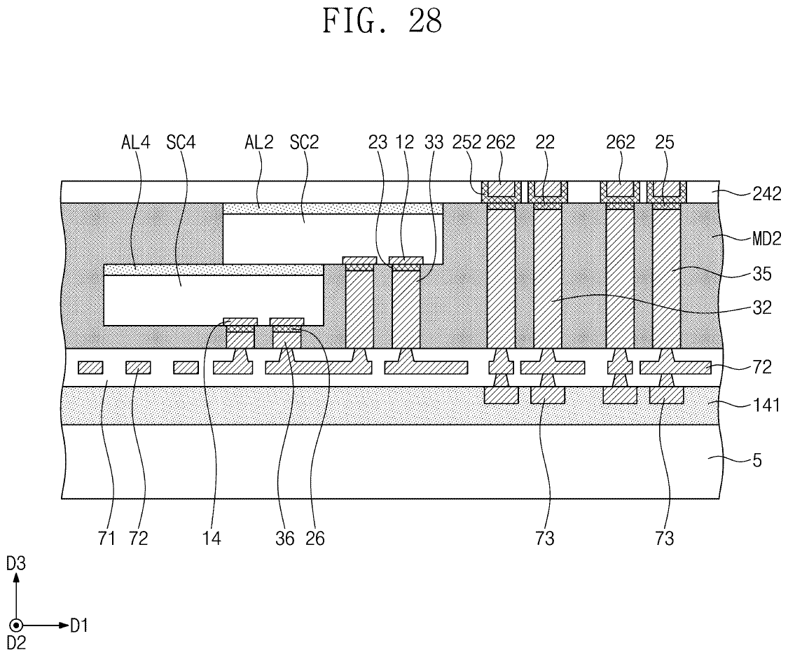

In FIG. 28, an upper portion of the second preliminary seed layer 223 and an upper portion of the second preliminary conductive layer 224 may be removed. For example, the upper portion of the second preliminary seed layer 223 and the upper portion of the second preliminary conductive layer 224 may be removed in a chemical mechanical polishing (CMP) process.

The upper portion of the second preliminary seed layer 223 may be removed to form the second bonding seed layers 252. The upper portion of the second preliminary conductive layer 224 may be removed to form the second bonding conductive layers 262.

In FIG. 24, the first and second bonding conductive layers 261 and 262 may be bonded to each other, the first and second bonding seed layers 251 and 252 may be bonded to each other, and the first and second bonding insulating layers 241 and 242 may be bonded to each other. Thereafter, a subsequent process may be performed.

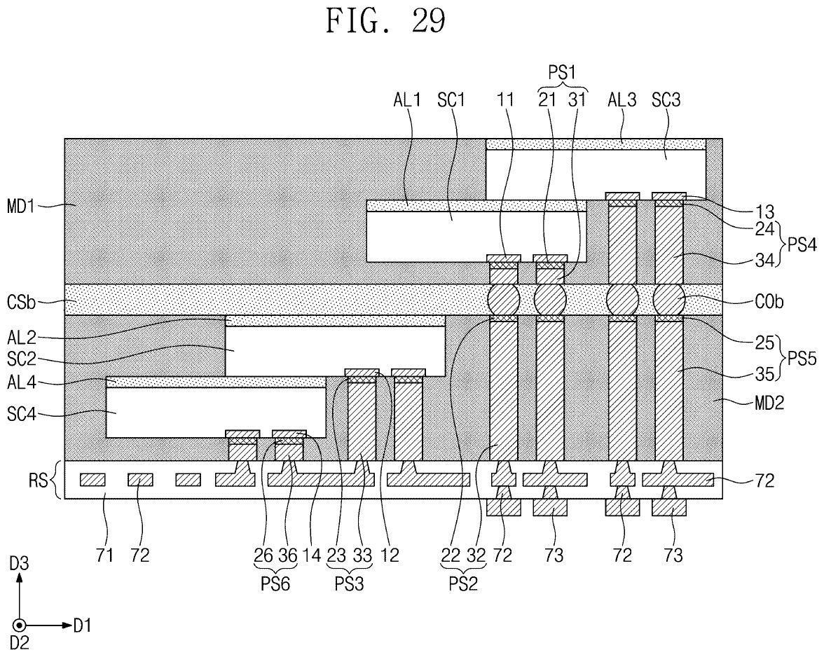

FIG. 29 is a cross-sectional view of an example of a semiconductor package according to some implementations. Except for what is subsequently described, the semiconductor package according to FIG. 29 may be similar to the semiconductor package according to FIGS. 1A and 1B.

In FIG. 29, a connection structure CSb may be a single layer. The connection structure CSb may include a different material from the first and second molding layers MD1 and MD2. For example, the connection structure CSb may include a non-conductive film (NCF).

A conductive structure COb may be a single structure. For example, the conductive structure COb may be a solder ball.

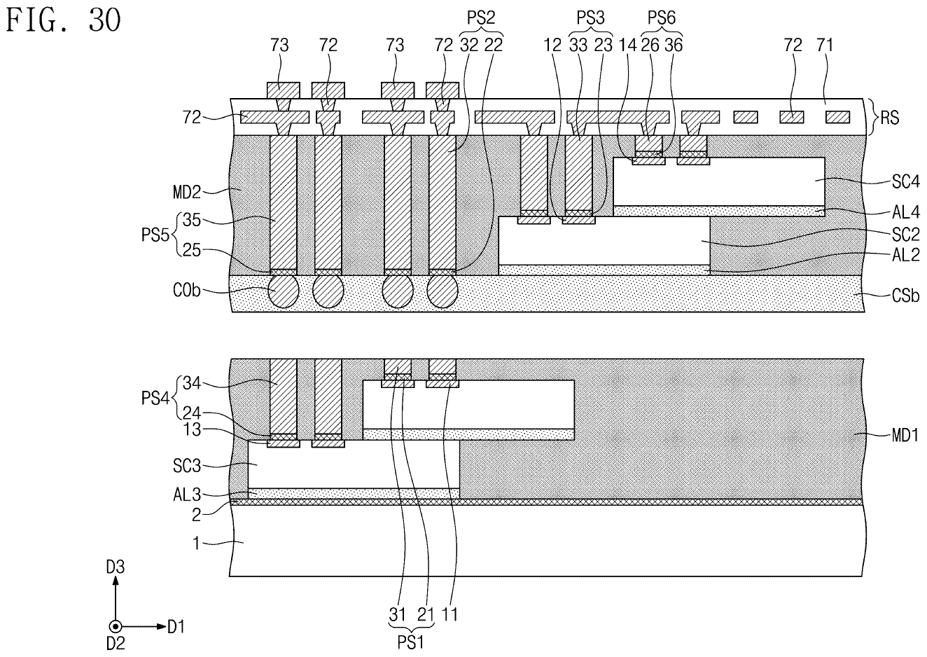

FIG. 30 is a diagram for describing an example of a method for manufacturing a semiconductor package according to some implementations. Except for what is subsequently described, the method for manufacturing a semiconductor package according to FIG. 30 may be similar to the method for manufacturing a semiconductor package according to FIGS. 2 and 22.

In FIG. 30, the conductive structures COb in contact with the second and fifth post seed layers 22 and 25 may be formed. The connection structure CSb surrounding the conductive structure COb may be formed.

In FIG. 29, the conductive structure COb may be brought into contact with the first and fourth post seed layers 21 and 24, and the connection structure CSb may be brought into contact with the first molding layer MD1. Subsequently, the scribing process may be performed.

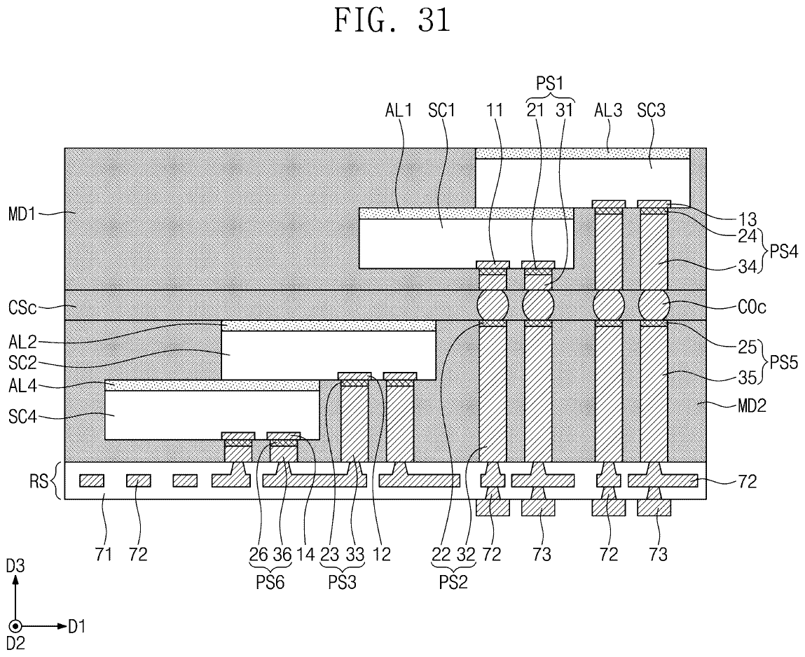

FIG. 31 is a cross-sectional view of an example of a semiconductor package according to some implementations. Except for what is subsequently described, the semiconductor package according to FIG. 31 may be similar to the semiconductor package according to FIGS. 1A and 1B.

In FIG. 31, a connection structure CSc may be a single layer. The connection structure CSc may include the same material as the first and second molding layers MD1 and MD2. For example, the connection structure CSc may include an epoxy molding compound (EMC). According to some implementations, the connection structure CSc may include a different material from the first and second molding layers MD1 and MD2.

The connection structure CSc may be a single structure. For example, the connection structure CSc may be a solder ball.

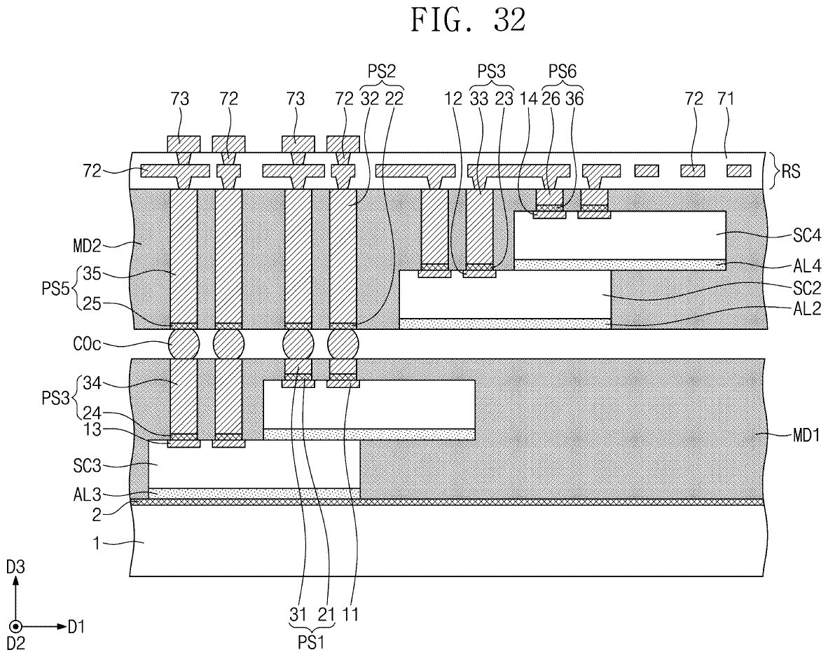

FIG. 32 is a diagram for describing an example of a method for manufacturing a semiconductor package according to some implementations. Except for what is subsequently described, the method for manufacturing a semiconductor package according to FIG. 32 may be similar to the method for manufacturing a semiconductor package according to FIGS. 2 to 22.

In FIG. 32, the conductive structures COc in contact with the second and fifth post seed layers 22 and 25 may be formed. The conductive structures COc may be brought into contact with the first and fourth post seed layers 21 and 24.

In FIG. 31, the connection structure CSc surrounding the conductive structures COc may be formed. The connection structure CSc may be formed in an underfill process. Subsequently, the scribing process may be performed.

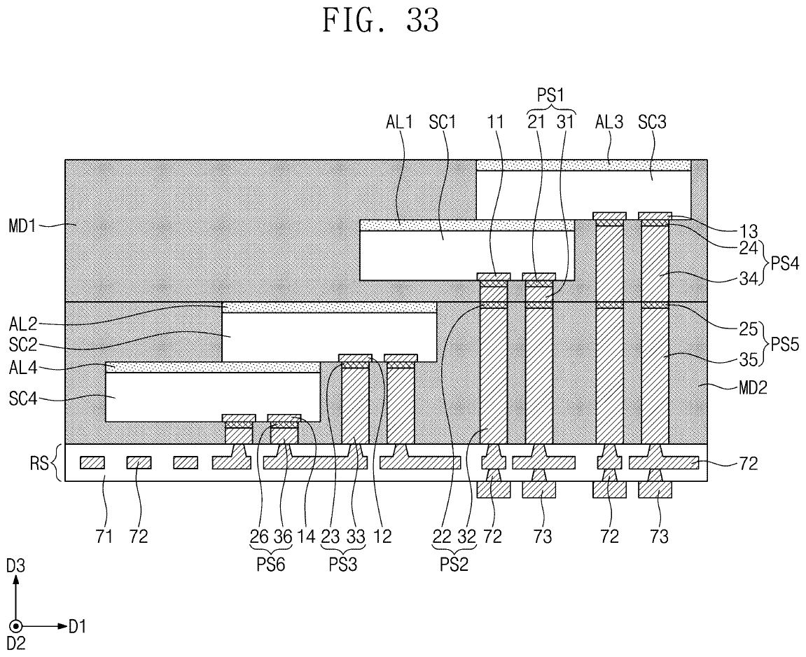

FIG. 33 is a cross-sectional view of an example of a semiconductor package according to some implementations. Except for what is subsequently described, the semiconductor package according to FIG. 33 may be similar to the semiconductor package according to FIGS. 1A and 1B.

In FIG. 33, the second molding layer MD2 and the second adhesive layer AL2 may be in contact with the first molding layer MD1. According to some implementations, the first molding layer MD1 and the second molding layer MD2 may have a structure integrally connected to each other without a boundary.

The second post seed layer 22 may be in contact with the first post 31. The fifth post seed layer 25 may be in contact with the fourth post 34.

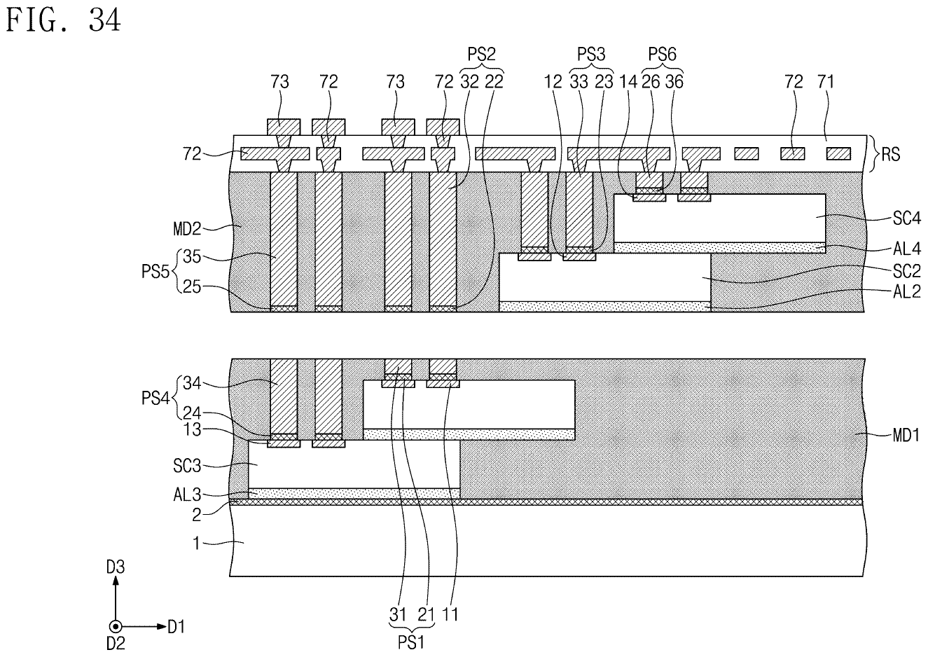

FIG. 34 is a diagram for describing an example of a method for manufacturing a semiconductor package according to some implementations. Except for what is subsequently described, the method for manufacturing a semiconductor package according to FIG. 34 may be similar to the method for manufacturing a semiconductor package according to FIGS. 2 to 22.

In FIG. 34, similarly to what is described in FIGS. 2 to 6, the first carrier substrate 1, the first sacrificial layer 2, the first and third adhesive layers AL1 and AL3, the first and third semiconductor chips SC1 and SC3, the first and fourth post seed layers 21 and 24, the first and fourth posts 31 and 34, and the first molding layer MD1 may be formed. The process of semi-curing the first molding layer MD1 may be performed. For example, the process of semi-curing the first molding layer MD1 may include an annealing process.

Similarly to what is described in FIGS. 10 to 17, the third carrier substrate 5 (see FIGS. 16 and 17), the glue layer 141 (see FIGS. 16 and 17), the terminals 73, the redistribution patterns 72, the photosensitive insulating layer 71, the second, third, fifth, and sixth post seed layers 22, 23, 25, and 26, the second, third, fifth, and sixth posts 32, 33, 35, and 36, the second and fourth adhesive layers AL2 and AL4, the second and fourth semiconductor chips SC2 and SC4, and the second molding layer MD2 may be formed. The process of semi-curing the second molding layer MD2 may be performed. For example, the process of semi-curing the second molding layer MD2 may include an annealing process.

A tape may be attached to the second molding layer MD2 and the second adhesive layer AL2, and the third carrier substrate 5 and the glue layer 141 may be removed.

In FIGS. 33 and 34, the wafer bonding process may be performed. The wafer bonding process may include separating the second molding layer MD2 from the tape, bonding the second molding layer MD2 to the first molding layer MD1, bonding the second post seed layer 22 to the first post 31, and bonding the fifth post seed layer 25 to the fourth post 34.

A curing process may be performed. For example, the curing process may include an annealing process. The first molding layer MD1 and the second molding layer MD2 may be completely cured in the curing process, and may be coupled to each other. According to some implementations, the first molding layer MD1 and the second molding layer MD2 may have a structure integrally connected to each other without a boundary in the curing process. According to some implementations, in the curing process, the second post seed layer 22 and the first post 31 may be coupled to each other, and the fifth post seed layer 25 and the fourth post 34 may be coupled to each other.

Subsequently, the scribing process may be performed.

In a semiconductor package, reliability of electrical connection between post structures may be improved.

In a method for manufacturing a semiconductor package, since an upper structure and a lower structure are separately manufactured, stability of processes of manufacturing the upper structure and the lower structure may be improved.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a first semiconductor chip;
a first molding layer surrounding the first semiconductor chip;
a first post structure in the first molding layer;
a second semiconductor chip;
a second molding layer surrounding the second semiconductor chip;
a second post structure in the second molding layer;
a connection structure between the first molding layer and the second molding layer; and
a conductive structure surrounded by the connection structure and disposed between the first post structure and the second post structure,
wherein the first post structure, the second post structure, and the conductive structure overlap the first semiconductor chip.

2. The semiconductor package of claim 1, wherein the connection structure comprises a material different from a material of the first molding layer and the second molding layer.

3. The semiconductor package of claim 1,
wherein the first post structure comprises a first post seed layer and a first post,
wherein the second post structure comprises a second post seed layer and a second post, and
wherein the conductive structure, the second post seed layer, and the first post are between the first post seed layer and the second post.

4. The semiconductor package of claim 3, wherein the conductive structure contacts the second post seed layer and the first post.

5. The semiconductor package of claim 1,
wherein an upper surface of the conductive structure and an upper surface of the connection structure are coplanar with each other, and
wherein a lower surface of the conductive structure and a lower surface of the connection structure are coplanar with each other.

6. The semiconductor package of claim 5,
wherein the lower surface of the connection structure contacts an upper surface of the second molding layer, and
wherein the upper surface of the connection structure contacts a lower surface of the first molding layer.

7. The semiconductor package of claim 1, wherein a sidewall of the first molding layer, a sidewall of the second molding layer, and a sidewall of the connection structure are coplanar with each other.

8. A semiconductor package comprising:
a first semiconductor chip;
a first molding layer surrounding the first semiconductor chip;
a first post structure in the first molding layer;
a second semiconductor chip;
a second molding layer surrounding the second semiconductor chip;
a second post structure in the second molding layer;
a connection structure between the first molding layer and the second molding layer; and
a conductive structure surrounded by the connection structure, and disposed between the first post structure and the second post structure,
wherein the first post structure, the second post structure, and the conductive structure are electrically connected to the first semiconductor chip.

9. The semiconductor package of claim 8,
wherein the connection structure comprises:
a first bonding insulating layer contacting the first molding layer;
a second bonding insulating layer contacting the first bonding insulating layer and the second molding layer;
a first bonding pad in the first bonding insulating layer; and
a second bonding pad in the second bonding insulating layer, and
wherein the second bonding pad contacts the first bonding pad.

10. The semiconductor package of claim 9,
wherein the first bonding pad comprises a first bonding seed layer contacting the first post structure, and a first bonding conductive layer contacting the first bonding seed layer,
wherein the second bonding pad comprises a second bonding seed layer contacting the second post structure, and a second bonding conductive layer contacting the second bonding seed layer, and
wherein the first bonding conductive layer and the second bonding conductive layer are between the first bonding seed layer and the second bonding seed layer.

11. The semiconductor package of claim 10,
wherein the first post structure comprises a first post seed layer contacting the first semiconductor chip and a first post contacting the first bonding seed layer, and
wherein the second post structure comprises a second post seed layer contacting the second bonding seed layer and a second post spaced apart from the second bonding seed layer.

12. The semiconductor package of claim 10,
wherein the first bonding seed layer surrounds the first bonding conductive layer,
wherein the second bonding seed layer surrounds the second bonding conductive layer, and
wherein the first bonding seed layer contacts the second bonding seed layer.

13. The semiconductor package of claim 10,
wherein the first bonding seed layer contacts the first molding layer, and
wherein the second bonding seed layer contacts the second molding layer.

14. The semiconductor package of claim 9, wherein a width of the first bonding pad and a width of the second bonding pad are greater than a width of the first post structure and a width of the second post structure.

15. The semiconductor package of claim 8, comprising an adhesive layer between the second semiconductor chip and the connection structure,
wherein the adhesive layer contacts the second semiconductor chip and the connection structure.

16. A semiconductor package comprising:
a first semiconductor chip including a first pad;
a first adhesive layer contacting an upper surface of the first semiconductor chip;
a first molding layer surrounding the first semiconductor chip and the first adhesive layer;
a first post structure surrounded by the first molding layer, the first post structure contacting the first pad;
a second semiconductor chip including a second pad;
a second adhesive layer contacting an upper surface of the second semiconductor chip;
a second molding layer surrounding the second semiconductor chip and the second adhesive layer;
a second post structure surrounded by the second molding layer and overlapping the first post structure;
a third post structure surrounded by the second molding layer, the third post structure contacting the second pad;
a connection structure between the first molding layer and the second molding layer; and
a conductive structure surrounded by the connection structure and disposed between the first post structure and the second post structure,
wherein the first post structure includes a first post seed layer contacting the first pad and a first post contacting the conductive structure,
wherein the second post structure includes a second post seed layer contacting the conductive structure and a second post contacting the second post seed layer, and
wherein the third post structure includes a third post seed layer contacting the second pad and a third post contacting the third post seed layer.

17. The semiconductor package of claim 16, wherein the first pad, the first post seed layer, the first post, the conductive structure, the second post seed layer, and the second post overlap each other.

18. The semiconductor package of claim 16,
wherein the first molding layer comprises an interposed portion between the first semiconductor chip and the connection structure, and
wherein the interposed portion surrounds the first post seed layer and the first post.

19. The semiconductor package of claim 16,
wherein an upper surface of the conductive structure contacts a lower surface of the first molding layer, and
wherein a lower surface of the conductive structure contacts an upper surface of the second molding layer.

20. The semiconductor package of claim 16, wherein an upper surface of the second molding layer and an upper surface of the second adhesive layer contact a lower surface of the connection structure.
